(19) United States
(12) Patent Application Publication
(10) Pub. No.: US 2005/0284514 A1
(43) Pub. Date: Dec. 29, 2005

(54) Organic electronic element with electronically conductive semitransparent layer

(76) Inventor: Christoph Brabec, Linz (AT)

Correspondence Address: FISH & RICHARDSON PC, P.O. BOX 1022, MINNEAPOLIS, MN, 55440-1022, US

(21) Appl. No.: 11/154,082

(22) Filed: Jun. 16, 2005

(30) Foreign Application Priority Data
Jun. 24, 2004 (DE) 102004030628.1

(51) Int. Cl. H01B 1/08; H01L 31/0224; H01L 31/04; H01L 33/00; H05B 33/28; G02F 1/15

(52) U.S. Cl. 136/243; 428/697; 428/702; 428/917; 313/503; 359/265

(57) ABSTRACT

The invention concerns an organic electronic element comprising a conductive semitransparent layer, of the kind that can be used, for example, as an electrode for a photovoltaic element or solar cell. A novel material for the transparent electrode is proposed that is less expensive than the ITO customarily used heretofore and has already achieved similar conductivities in initial tests.

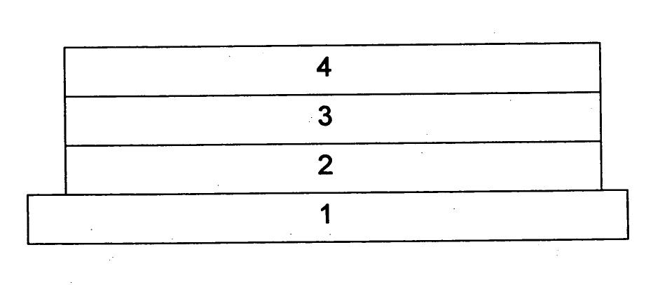

The invention concerns an electronic element comprising at least one organic active functional layer and one novel conductive semitransparent or transparent layer, of the kind that can be used, for example, as an electrode for an organic photovoltaic element or solar cell.

There are a great many types of electronic components made from predominantly organic material, of which the group comprised of photovoltaic elements—solar cells or photodetectors, electrochromic elements and self-emissive devices, such as light-emitting diodes—are [sic] distinguished by the fact that at least one of the electrodes is ostensibly transparent to light, i.e., at least semitransparent. This group of organic, electronic components provided with a semitransparent electrode or semitransparent electrically conductive layer conventionally includes a positive electrode made of ITO (indium tin oxide); there are few alternatives to this material that are susceptible to use in organic electronics, since the production methods for creating the electrode layer must be adapted to the subsequent organic layers sufficiently so that an upper layer does not damage any of the lower layers during production and the work function of the electrode is adapted to the organic semiconductor layer. So far there has been no alternative to ITO that meets this condition, since ITO fulfills both the transparency and work function requirements and the stability requirements that prevail during the production of organic layers.

An especially critical factor is that the lower layer or portions thereof not be dissolved during the application of the upper layer.

Hence, there is a need to provide additional materials that are suitable for the construction of an organic electronic component comprising a semitransparent, electrically conductive layer.

The object of the present invention is, therefore, to provide a material which with respect to at least one of the properties stability, work function, conductivity, transparency and surface roughness is within a range that enables it to be used in organic photovoltaics, for organic photodetectors, in organic self-emissive diodes or light-emitting diodes and/or in organic electrochromic elements. It is important that the conductivity and the work function of such an electrode material be adapted to the organic functional layer concerned, the energy levels of the HOMO/LUMO orbitals of the compounds being critical.

The invention is directed to an organic electronic component comprising two electrodes and at least one organic active functional layer that is photosensitive, i.e., either photovoltaically active, electrochromic and/or emissive, in which at least one of the electrodes and/or the electrically conductive layer contains zinc oxide. The invention is further directed to the use of zinc oxide and/or zinc-oxide-containing mixed oxides for transparent electrodes of organic electronic components.

Surprisingly, it has been found that the inorganic electrode layer of doped zinc oxide that has long been used in inorganic, conventional semiconductor electronics is also suitable for organic semiconductors.

“Organic electronic component comprising at least two electrodes and one active functional layer that is photosensitive, i.e., for example photovoltaically active,” means, for example, a solar cell and/or a photodetector. An organic electronic component so constructed and comprising an electrochromic functional layer is, for example, an organic electrochromic element such as a display or an organic display unit. Finally, it is understood that, for example, “organic electronic component comprising an emissive functional layer” includes, for example, a light-emitting diode or OLED or a so-called “self-emissive device.” The present invention can be used for all the elements and components recited here and for others comprising transparent electrodes. The invention has been developed particularly in connection with organic electronic components.

The term “semitransparent and/or transparent electrode” here denotes any so-called window electrode that is transparent to light, so that light is able to pass through it to the, for example, organic functional layer(s) or from the functional layer(s) to the outside. Even glass has a transparency of “only” about 95%, and is therefore basically only “semitransparent.” Transparent electrodes are encompassed by the invention, but it is usually necessary to make do with semitransparent electrodes.

Advantageously, the transparent electrode or conductive layer contains a not insubstantial fraction of zinc oxide (ZnO), for example more than 95% by weight, preferably more than 98%, in the form of a doped zinc oxide (i.e., in which the first compound is present in a very pure form, with few or no impurities, and the second compound is present in an amount equal to less than 1.5% by weight), doped, for example, with aluminum oxide, pure aluminum or fluorine, or boron-doped zinc oxide, and/or in the form of a zinc oxide containing a fraction of aluminum oxide (Al₂O₃) equal to between 0.5 and 3% by weight.

In one embodiment, the semitransparent, electrically conductive layer is a mixed oxide composed of zinc oxide and/or aluminum oxide, which is available under the tradename AZOY. Surprisingly, it has been found that this material, which has already proven useful in the field of inorganic photovoltaics, can also be used for organic photovoltaics.

One advantage of the electrode of an inventive component over conventional, ITO-containing electrodes is that the material also accords with the organic active layers but is much less expensive.

An embodiment of the inventive component is described in more detail below with reference to a figure.

The FIGURE shows an electronic component, for example one made from predominantly organic material, comprising a substrate 1, for example of transparent film or glass; a transparent bottom electrode 2; at least one active functional layer made of organic material 3; and a top electrode 4. Transparent bottom electrode 2 contains a zinc oxide fraction.

In tests, electronic components comprising transparent electrodes fabricated on the basis of zinc oxide have proven nearly as fast and reliable as those constructed with the ITO customarily used heretofore. The material proposed here is substantially less expensive and easier to obtain for the bottom electrode.

A suitable photoactive layer or a suitable organic functional polymer or an organic active semiconductor layer is known, inter alia, from U.S. Pat. No. 5,454,880, and can comprise one or more semiconductive synthetic materials, which can be present as monomer, oligomer and/or polymer, plus inorganic particles and/or nanoparticles. A mixture of two or more conjugated organic synthetic materials, inorganic particles and/or nanoparticles having similar or different electron affinities and/or similar or different band gaps can be present.

The term “polymer” in “polymer solar cell,” “organic material” [sic] or “functional polymer” here comprises all types of organic, metalorganic and/or organic/inorganic synthetic materials and (hybrids) that are photovoltaically active. For example, it signifies all such materials denoted in English by terms such as “plastics.” This includes all types of materials except for semiconductors used for conventional diodes (germanium, silicon) and typical metallic conductors. Thus, no limitation is intended in the dogmatic sense to organic material as carbon-containing material, but rather, the widespread use of, for example, silicones is also contemplated. Furthermore, the term is not intended to imply any limitation with respect to molecular size, particularly to polymeric and/or oligomeric materials, but rather, the use of “small molecules” is also thoroughly feasible. The word “polymer” in “functional polymer” is historically rooted and to this extent makes no statement as to the presence of an actual polymeric compound. The term “functional polymer” can mean semiconductive, conductive and/or insulating materials.

The invention concerns an electronic element, preferably one composed of predominantly organic material and comprising a conductive semitransparent layer, of the kind that can be used, for example, as an electrode for a photovoltaic element or solar cell. A novel material for the transparent electrode is presented that is less expensive than the ITO customarily used heretofore and has already achieved similar conductivities in initial tests.

1. An electronic components comprising:
at least two electrodes; and
an organic functional layer that is photovoltaically active, electrochromic and/or emissive,
wherein at least one of the electrodes, the electrically conductive layer or both contains zinc oxide.

2. The electronic component as claimed in claim 1, wherein at least one of the electrodes contains a zinc-oxide-containing mixed oxide or a doped zinc oxide.

3. The electronic component as claimed in claim 1, wherein the at least one of the electrodes contains a mixed oxide composed of zinc and aluminum.

4. A method, comprising:
using doped or undoped zinc oxide and/or zinc-oxide-containing mixed oxides for electrodes of organic electronic components.

5. (canceled)

6. A method, comprising:
using doped or undoped zinc oxide for at least one electrode of a solar cell comprising a functional organic semiconductor layer.

7. An electronic components comprising:
a first electrode;
a second electrode; and
an organic functional layer between the first and second electrodes, the organic functional layer being selected from the group consisting of photovoltaically active layers, electrochromic players, emissive layers, and combinations thereof,
wherein at least one member selected from the group consisting of the first electrode, the second electrode and the organic functional layer contains zinc oxide.

8. The electronic component of claim 7, wherein the first electrode contains zinc oxide.

9. The electronic component of claim 8, wherein the second electrode contains zinc oxide.

10. The electronic component of claim 9, wherein the organic functional layer contains zinc oxide.

11. The electronic component of claim 7, wherein the organic functional layer contains zinc oxide.

12. The electronic component of claim 7, wherein the first electrode contains a zinc-oxide-containing mixed oxide or a doped zinc oxide.

13. The electronic component of claim 12, wherein the second electrode contains a zinc-oxide-containing mixed oxide or a doped zinc oxide.

14. The electronic component of claim 13, wherein the organic functional layer contains a zinc-oxide-containing mixed oxide or a doped zinc oxide.

15. The electronic component of claim 7, wherein the organic functional layer contains a zinc-oxide-containing mixed oxide or a doped zinc oxide.

16. The electronic component of claim 7, wherein the first electrode contains a mixed oxide comprising of zinc and aluminum.

17. The electronic component of claim 16, wherein the second electrode contains a mixed oxide comprising of zinc and aluminum.

18. The electronic component of claim 17, wherein the organic functional layer contains a mixed oxide comprising of zinc and aluminum.

19. The electronic component of claim 7, wherein the organic functional layer contains a mixed oxide comprising of zinc and aluminum.

20. The electronic component of claim 7, wherein the electronic component is a photovoltaic cell.

21. The electronic component of claim 1, wherein the electronic component is a photovoltaic cell.
